(19) United States
(12) Patent Application Publication
(10) Pub. No.: US 2002/0113588 A1
(43) Pub. Date: Aug. 22, 2002

(54) SQUID array magnometer with multi-frequency induction

(76) Inventors: Michelle A. Espy, Los Alamos, NM (US); John C. Mosher, Los Alamos, NM (US); Robert H. Kraus JR., Los Alamos, NM (US)

Correspondence Address: MADSON & METCALF, GATEWAY TOWER WEST, SUITE 900, 15 WEST SOUTH TEMPLE, SALT LAKE CITY, UT, 84101

(21) Appl. No.: 09/957,687

(22) Filed: Sep. 19, 2001

Related U.S. Application Data
(60) Provisional application No. 60/234,460, filed on Sep. 21, 2000.

(51) Int. Cl. G01R 33/02

(52) U.S. Cl. 324/239; 324/248; 324/235

(57) ABSTRACT

The present invention provides an improved magnetometer to efficiently evaluate subsurface characteristics of conductive material without destroying the material. A white noise generator drives an induction coil to induce measurable currents in a work piece at multiple frequencies. Multiple super conducting quantum interference devices (SQUIDs) measure the magnetic filed created by the currents. The SQUIDs are housed in a liquid nitrogen Dewar. The SQUIDs are aligned along a Josephson junction and are manufactured on a single substrate. A mover moves the work piece adjacent the super conducting quantum interference devices. A computer analyzes the measured data.

### RELATED APPLICATIONS

The present application is related to, and claims priority from, U.S. Provisional Application No. 60/234,460, entitled “Squid Array Microscope with Multi-Frequency Induction,” filed Sep. 21, 2000, which is hereby incorporated by reference in its entirety.

### GOVERNMENT RIGHTS

This invention was made with Government support under Contract Number W-7405-ENG-36 awarded by the United States Department of Energy to The Regents of the University of California. The Government has certain rights in the invention.

### BACKGROUND OF THE INVENTION

1. Field of the Invention

The present invention relates generally to non-destructive testing of conductive objects. More particularly, the present invention relates to a magnetometer used to detect features and qualities of conductive objects below the surface using an array of super conducting quantum interference devices to detect magnetic field anomalies.

2. Description of Related Art

The examination of conductive materials is a requirement in many industries and government agencies. As inventories and stockpiles age, it becomes necessary to check the structural integrity of many items. In some instances, stockpiles are examined by sampling a selected number of the items within the stockpile and drawing conclusion regarding the remaining items. The evaluation process, however, destroys the sample item, and you still are left with only estimates regarding the structural makeup of the non-sampled items. Often similar items age differently and anomalies absent in one sampled item may exist in all or some of the other items.

As a way to help overcome the cost of destructively evaluating samples of items or materials, various methods have been employed. One such method involved ultrasonic evaluation. The problem with ultrasonic evaluation, however, is that it is affected by intervening non-conducting layers which prevent seeing features below such layers. Another non destructive evaluation technique involved the use of magnetometers. Magnetometers are instruments for measuring the magnitude and sometimes also the direction of a magnetic field. Known magnetometers may induce a current in the work piece and measure the resulting feedback from the work piece to glean information regarding the qualities and characteristics of the work piece.

The problem with known induced-current magnetometers is that they only gather data at a single frequency, which provides a one-dimensional picture of the qualities or characteristics of the item at a particular point. If additional data is desired, the frequency must be changed and the item reevaluated. Collecting any meaningful data from the work piece is extremely time consuming, which increases costs. Additionally, most measuring devices cannot determine characteristics or qualities of the evaluated object or item much below the surface level. Further, known magnetometers provide poor spatial resolution of the characteristics or anomalies within the evaluated object or work piece.

Therefore, it would be advantageous in the art to provide a magnetometer capable of more efficient and non-destructive measuring and evaluation of objects or work pieces. It would be a further advancement in the art to provide a magnetometer with increased spatial resolution. It would be an additional advancement to provide a magnetometer that can evaluate qualities and characteristics at a greater depth in the material. Such a device is disclosed and claimed herein.

### BRIEF SUMMARY OF THE INVENTION

The present invention is directed towards a magnetometer for measuring magnetic fields caused by eddy currents in a sample or work piece. The magnetometer may include an induction coil driven by a white noise generator for inducing eddy-currents and corresponding magnetic fields in a work piece at multiple frequencies. The white noise generator allows the magnetometer to simultaneously stimulate the work piece at multiple frequencies so that information can be gathered about varying depths in the work piece during a single scan.

A magnetic field detector may include a plurality of super conducting quantum interference devices (“SQUIDs”) manufactured from a single substrate for detecting and measuring the eddy-currents or magnetic field in the work piece. The SQUIDs may each have a thirty degree bicrystal Josephson junction. In one embodiment, the SQUIDs are linearly aligned along the Josephson junctions. The array of SQUIDs provides increased spatial resolution of the measured characteristics of the work piece being evaluated.

A fiberglass Dewar may contain a liquid nitrogen bath. The induction coil and array of SQUIDs may rest within the nitrogen bath. The Dewar may have a minimum thickness of about four millimeters which allows the array of SQUIDs to be positioned close to the work piece being evaluated.

A mover for moving the work piece adjacent the SQUIDs under the Dewar may include a stepper motor which allows the work piece to be moved in multiple directions. A computer permits analysis of measured currents or magnetic fields in the work piece and controls the scanning of the work piece.

Accordingly, the magnetometer of the present invention provides the ability to detect small features buried at various depths in the work piece and also provides quantitative information about the depths at which the features are present. The combination of the array of super conductive interference devices and the white-noise induction scheme allows one to take a “cube” of date. For example, one could scan the array in a single direction over the sample, obtaining a two-dimensional picture, and then use the depth information for the third dimension. Or one could leave the array fixed in space, and watch features evolve in time. It should be noted, the white-noise technique allows one to acquire all frequencies, and hence the depths, simultaneously. This significantly speeds up the acquisition time. The magnetometer of the present invention is a tool for non-destructive testing of conductive objects that has unsurpassed sensitivity.

Accordingly, the potential uses of the magnetometer exist in the airline, shipping, and automotive industries. The magnetometer would also be useful for testing features of weapons components, a situation where disassembly of the object under test is not only very costly, but dangerous. The instrument would also be suited for industrial applications such as quality control and inspections for damage.

Various advantages and novel features of the invention will be set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF DESCRIPTION OF THE DRAWINGS

A more particular description of the invention briefly described above will be rendered by reference to the appended drawings. Understanding that these drawings only provide information concerning typical embodiments of the invention and are not therefore to be considered limiting of its scope, the invention will be described and explained with additional specificity and detail through the use of the accompanying drawings, in which:

FIG. 1 is a perspective view of a magnetometer within the scope of the present invention;

FIG. 2 is one embodiment of the magnetic field detector of FIG. 1 illustrating an array of Super Conducting Interference Devices (“SQUIDs”);

FIG. 3 is a block diagram of the magnetometer of FIG. 1;

FIG. 4 is side cross-sectional view of a portion of FIG. 1 showing a Dewar containing a magnetic field generator and a magnetic field detector;

FIG. 5 is a set of graphs showing spatial resolution of one embodiment of the magnetometer accordingly to the present invention;

FIG. 6 is a graph and illustration showing spatial resolution with localized current sources and magnetic field detector employing an array of seven SQUIDs;

FIGS. 7A through 7D are a set of graphs illustrating amplitude reading in a work piece for different frequencies of one embodiment of the magnetometer of the present invention; and

FIG. 8 illustrates the comparative amplitude of two holes in the evaluated work piece as a function of frequency.

It should be understood that the drawings of the devices are not necessarily to scale and that the embodiments are sometimes illustrated by graphic symbols, diagrammatic representations; and fragmentary views. In certain instances, details which are not necessary for an understanding of the present invention or which render other details difficult to perceive may have been omitted. It should be understood, of course, that the invention is not necessarily limited to the particular embodiments illustrated herein.

### DETAILED DESCRIPTION OF THE PREFERRED EMBODIMENTS

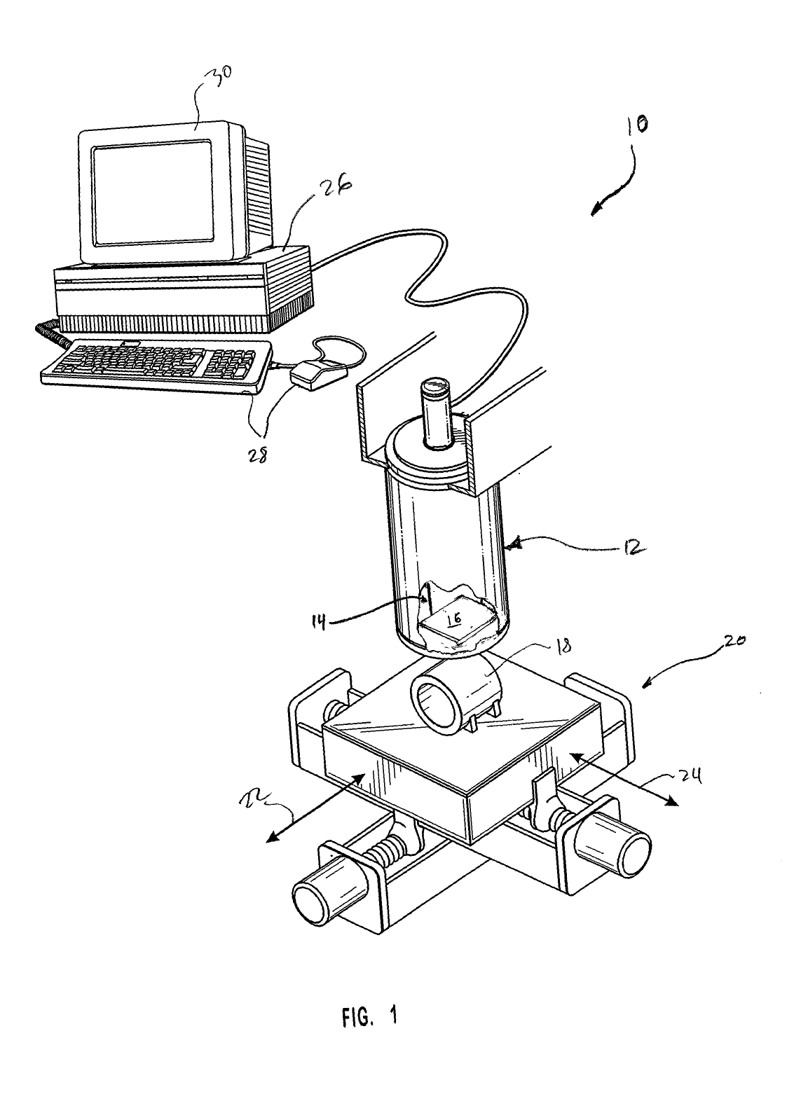

It will be readily understood that the components of the present invention, as generally described and illustrated in the Figures herein, could be arranged and designed in a wide variety of different configurations. Thus, the following more detailed description of the embodiments of the system and method of the present invention, as represented in the FIG. 1 through 8, is not intended to limit the scope of the invention, as claimed, but is merely representative of the presently preferred embodiments of the invention.

With reference to FIG. 1, a magnetometer according to the present invention is generally designated at 10. The magnetometer 10 may include a Dewar 12 for housing a magnetic field generator 14 that induces currents which create measurable magnetic fields in an object or work piece 18. A magnetic field detector 16 may also be housed in the Dewar 12 for measuring eddy-currents or magnetic field properties in the work piece 18. The work piece 18 may be moved beneath, and adjacent to, the magnetic field detector 16 and Dewar 12 by a mover 20. The mover 20 allows the work piece 18 to be moved in various combinations of a first direction 22 and a second direction 24. In one embodiment, the mover 20 may include a pair of stepper motors. The mover 20 may also include an X-Y table, or other dual-axis translation stage, associated with the stepper motors. Accordingly, the Dewar 12 may remain fixed while the work piece 18 is scanned beneath it in any combination of orthogonal directions 22, 24.

A computer 26 permits analysis of the measured data from the work piece 18. It may also control the mover 20 to control the positioning of the work piece 18 beneath the magnetic field detector 16. The computer 26 may include input devices 28 such as a keyboard and a mouse and an output device 30 such as a terminal.

The idea behind the operation of the magnetometer 10 is that magnetic fields provide external stimuli which induce eddy-currents in the work piece 18 under study. Deviations in the eddy-currents correspond to physical features such as seams, cracks, pits, or corrosion points in the object or work piece 18 under test. These eddy-currents and the magnetic fields they generate can be measured by the magnetic field detector 16 and corresponding outputs can be analyzed by the computer 26 to provide characteristics below the surface of the work piece 18. Thus, work pieces 18 can be examined for physical features that are not visible to the eye without the need to disassemble or dissect the work piece 18.

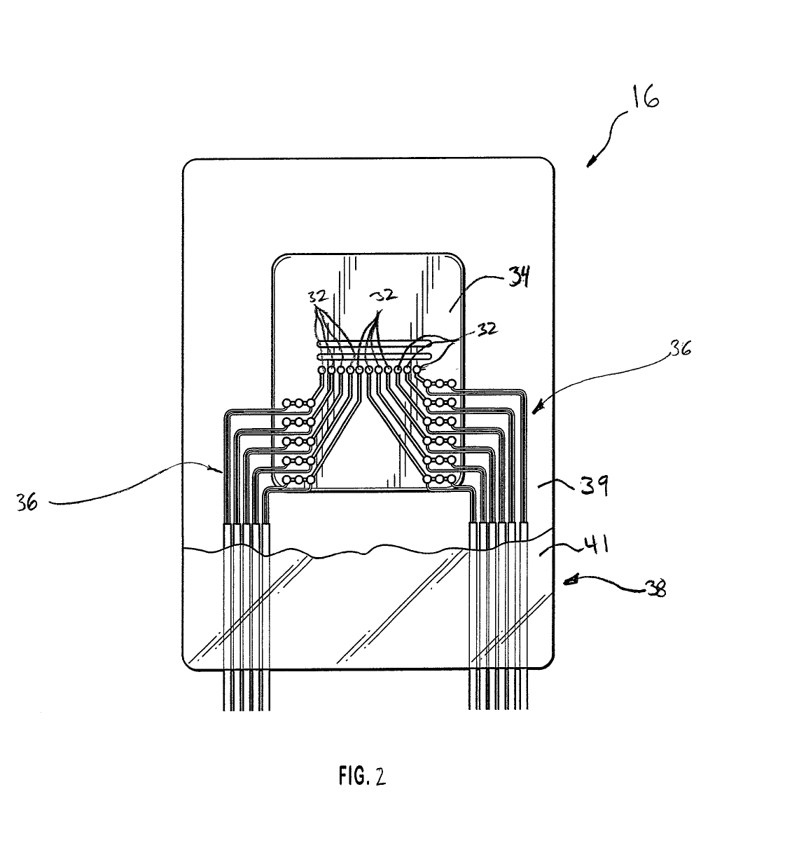

Referring now to FIG. 2, the magnetic field detector 16, may include a linear array of multiple Super Conducting Quantum Interference Devices (SQUIDs) 32. It will be appreciated that SQUIDs 32 are sensitive detectors of magnetic fields. The use of multiple SQUIDs 32 allows for improved spatial resolution as well as reduces the number of steps needed during a scan of a test object because multiple points in the work piece 18 are being scanned simultaneously by each SQUID 32. In the magnetic field detector 16 of the present invention, all the SQUIDs 32 are manufactured together on one substrate 34. This configuration helps ensure that each SQUID 32 is very similar in performance. In addition, well-known gradiometer schemes using more than one SQUID 32 (for example subtracting the signal from two or more SQUIDs) can be made very precisely because the SQUIDs 32 are aligned in a plane and precisely and linearly aligned along a Josephson Junction (not shown) within the substrate 34.

It will be appreciated that this configuration is more efficient and less complex than using arrays of many individual SQUIDs 32 on separate substrates 34. In one embodiment, the magnetic field detector 16 consists of eleven SQUIDs 32 each having a thirty-degree bicrystal Josephson junction. Each SQUID 32 is aligned at the Josephson junction. Each SQUID 32 may have a square 0.4 mm×0.4 mm loop with a field sensitivity of between about 20 nT/Φ₀ and about 180 nT/Φ₀. In one embodiment, the field sensitivity is about 100 nT/Φ₀. The inter-SQUID spacing on the substrate 34 may be less then one millimeter, and in one embodiment, the inter-SQUID spacing is about seven tenths of a millimeter.

In other embodiments, the field sensitivity and inter-SQUID spacing may vary according to need and the type of work piece 18 to be evaluated. Furthermore, the qualities and characteristics of the SQUIDs 32 may depend upon the type of substrate being used, and on other performance criteria. For example, spacing the SQUIDs 32 too close together may cause interference between individual SQUIDs 32 such that they would not produce independent readings of the work piece 18.

The magnetic field detector 16 may also include SQUID electronics 36 or a SQUID electronic system 36 for interconnecting each SQUID 32 with the computer 26, the magnetic field generator 14, and/or each other. In the embodiment illustrated in FIG. 2, the magnetic field detector 16 includes a covering 38 having bottom plate 39 and top plate 41. The plates 39, 41 may be made of variety of materials and may be sealed together to protect the substrate 34 and embedded SQUIDs 32.

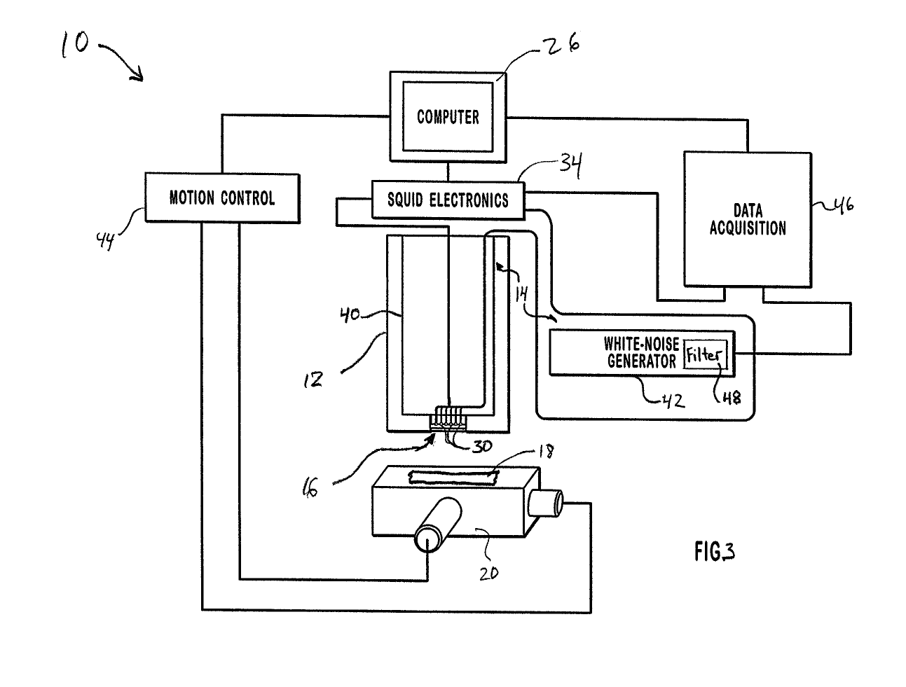

Referring now to FIG. 3, the current generator 14 may include an induction coil 40, located above the SQUIDs 32, for inducing eddy-currents (not shown) in the work piece 18. In one embodiment, the current generator 14 also includes a white-noise generator 42 that drives the induction coil 40 to produce an induction signal. This may be accomplished by using a standard random sequence driven into a standard amplifier system to create predetermined frequencies of interest. The frequency of the induction signal is the frequency at which the work piece 18 sample will respond (with a phase change). Different frequencies induce eddy-currents which reveal information at correspondingly different depths in the work piece 18. It will be appreciated that the white noise or random noise generator 42 allows the induction coil 40 to simultaneously produce induction signals at a range of desired frequencies. Accordingly, information can be gathered at various depths simultaneously. This, coupled with the movement of work piece 18 under multiple squids 32, provides three-dimensional cubes of data in a single pass. Simultaneously stimulating a band of frequencies also allows for rapid acquisition, and statistical processing of both the input and output, which allows stable characterization of the impulse response. By observing the response at different frequencies, one can infer depth information, since frequency is related to skin depth. Using noise excitation to simultaneously examine many frequencies, statistics can be used to account for uncontrolled errors.

The induction coils 40 may be designed to produce a null in the magnetic field at the SQUIDs 32. In one embodiment, this is accomplished by the design of the induction coil 40. It will be appreciated that various patterns of the induction coil 40 will cause a canceling effect on the induction signal at the desired location. Thus, the SQUIDs 32 primarily pick up the magnetic field associated with the induced currents in the sample, and very little magnetic field from the induction coils 40 themselves. Accordingly, a more accurate measurement of the work piece 18 characteristics may be obtained. The induction signal is also fed directly back to the SQUIDs 32 and/or SQUID electronics 36 to be accounted for in measuring the readings taken from the SQUIDs 32. Thus, any error from outside interference, rather than the desired eddy-current interference, is minimized.

The computer 26 controls the scan of the work piece 18 by interacting with a motion control module 44. At discrete steps in the scan, the response of each SQUID 32 in the array to the induction signal, may be recorded by an analog to digital converter within a data acquisition module 46. A channel of the analog to digital converter also records the induction signal itself. Thus, The computer also records the white noise signal used to drive the magnetic field generating induction coil 40. The computer 26 can also control the white noise generators settings. The data acquisition module may store the recorded data for use at a later time. The software in the computer 26 may take the signal from each SQUID 32 as well as the recorded induction signal and perform a spectral analysis of the two sequences. This software may then convert the data to the frequency domain.

Thus, a stable impulse response, also known in the frequency domain as a transfer function, may be calculated. By rapidly calculating the transfer function over many frequencies, the user may observe changes as a function of time, which is a further advantage of the present invention. Since the excitation and the response are both acquired simultaneously, the power spectrum of the noise is not assumed to be “white” or flat across the frequencies of interest. In one embodiment, the white noise generator 42 is considered “near white,” but in other embodiments, the noise could also be “colored” by shaping certain frequencies to have more or less power.

As will be discussed in greater detail below, properties such as transfer function and coherence are recorded to a file by the data acquisition module 46 for later analysis. During analysis this data provides the user with information about the relative phase and amplitude of the SQUID 32 response versus the induction signal at a desired range of frequencies. Such software may be commercially available, including MATLAB software by The Mathworks, Inc.

In alternative embodiments, different induction signals may be use to externally provide excitation within the work piece 18. In one embodiment, the external stimuli or signal may include an impulsive “spike,” a rectangular pulse or “step function,” or a sine wave. It will be appreciated that a sine wave must be generated for a reasonable settling time, before switching to the next frequency point, increasing measurement time. In each embodiment, measurements may be contaminated by additional noise and errors, so some combination of modeling, regularization, and averaging is provided to account for these uncontrolled errors. SQUID-array 32 magnetic field detectors 16 are particularly vulnerable to noise, making such error control a necessity.

The white-noise induction signal or other induction signals may be passed through a filter 48 to control the range of desired frequencies at which the induction signal affects the work piece 18. This allows an operator to focus power in a certain range of frequencies up to a low-pass filter 48 cut-off or down to a high-pass filter 48 cutoff that may be of interest, given the content of the work piece 18. It will be appreciated by those of skill in the art that different materials to be evaluated respond better to different ranges of frequencies. For example, aluminum will have an optimal range of induction signal frequencies for maximizing information measured in the work piece 18, that is different than the optimal range for galvanized steel. Further, different frequencies penetrate different materials to different depths and the present invention allows frequencies to be chosen according to the depth of information desired.

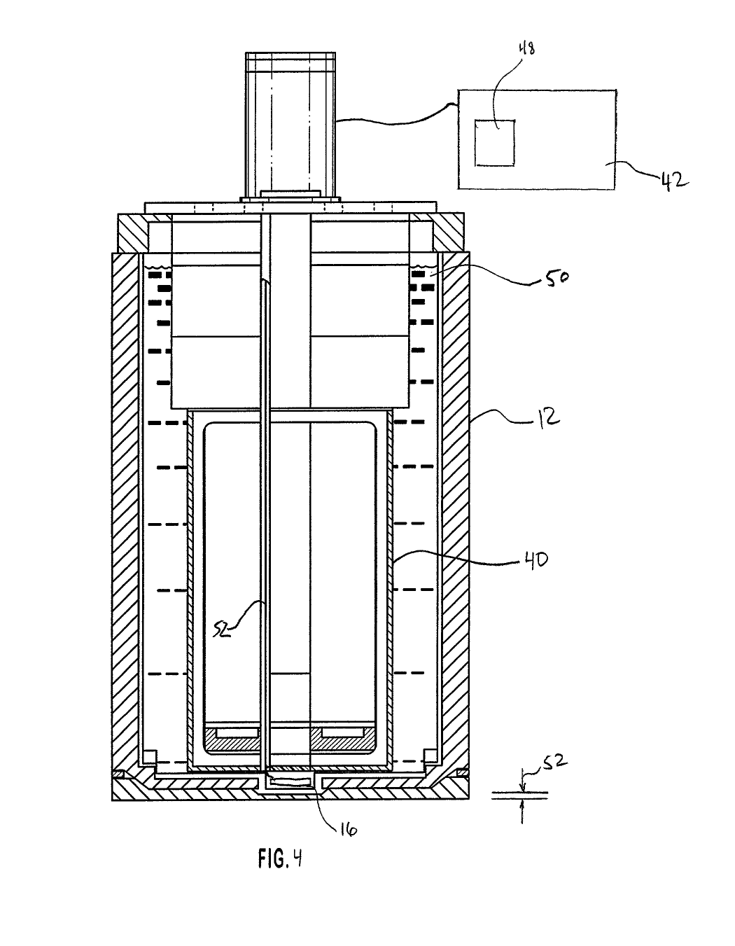

Referring now to FIG. 4, the Dewar 12 contains a liquid nitrogen bath 50. The array of SQUIDs 32 is placed in liquid nitrogen within the Dewar 12. The induction coil 40 is also placed within the liquid nitrogen bath 50 inside the Dewar 12. Liquid nitrogen provides the required low temperature and a stable and clean environment in which the SQUIDs 32 can efficiently operate. In one embodiment, the Dewar 12 is made of fiberglass, having a minimum thickness 52 less than about ten millimeters. In one embodiment, the minimal thickness of the Dewar is about four millimeters. Accordingly, the array of SQUIDs 32 is close to the work piece 18 being evaluated.

The method for testing work pieces 18 with the magnetometer 10 of the present invention, may include driving an induction coil 40 with a white noise generator 42 to induce eddy-currents in the work piece 18. The magnetic fields stimulated in the work piece 18 may be measured and analyzed to output information relating to characteristics of the work piece 18. The response of each SQUID 32 in the array of SQUIDs 32 may be measured along with the induction signal and then compared.

A basic premise of the white noise generator 42 is that both the noise sequence and the response sequence are measured. By way of illustration, if “x” represents the input sequence and “y” the output sequence, the power spectral density of x, or “Pxx”, can be generated. Likewise, the power spectral density of y or “Pyy” can be generated. The cross-spectral density Pxy between x and y can also be determined. The complex transfer function is then calculated as Pxy/Pxx, and the coherence function is calculated as (abs(Pxy)ˆ 2)/(Pxxˆ 2).

It will be appreciated by those of skill in the art that several methods are available for making these power spectral calculations. In one embodiment, the Welch Periodogram method is used, which averages several periodograms created from overlapping sequences of the data, creating a reasonably stable estimate and confidences about this estimate. The entire noise spectrum estimation process described above can be captured in the MATLAB software routine SPECTRUM.

Because of the high uncontrolled noise levels in SQUID-based measurements, the analysis of the measured data can be broken into two parts. First the coherence function generated in the calculations is examined to observe if the measured output sequence is linearly correlated with the stimulus. Frequencies at which the coherence function drops appreciably indicate possibly external noise contamination (e.g. power lines), ineffective stimulation such as impedance mismatches, or possible nonlinearities in the material under test. In those frequencies at which coherence is inadequate, the experimental paradigm must be adjusted to either move the array closer to the material, increase the overall excitation power, shape the excitation noise spectrum to have more power in deficient frequencies, or some combination of adjustments.

For sufficiently coherent frequencies, the complex transfer function is examined for its magnitude and its phase. Impulsive techniques do not have the simple ability to selectively ignore poorly coherent frequencies. Because the exact relationship between input and output is not known, changes in either amplitude or phase along the linear array of SQUIDs 32 are examined at these coherent frequencies. The examination of this data can be readily achieved graphically by plotting either quantity. Because frequency is inversely proportional to skin depth, a change in the lower frequencies but not the higher may indicate a deeper flaw in the work piece 18. Conversely, the opposite is also possible to detect, since shallow flaws impact more greatly the higher frequencies.

If the linear array of SQUIDs 32 is then stepped in a direction perpendicular to the line array, a “cube” of data can be built whose two sides represent the surface of the material being scanned, and whose third dimension represents spectral information and therefore depth into the material.

If the linear array of SQUIDs 32 is fixed in space, but the measurement is repeated many times under changing conditions in the material, then again a “cube” of data can be built, with one side representing a line along the material, another side the spectral or depth information, and the third side the change of this material as a function of time. In either of these approaches, the cube of data can be presented graphically to a user via the output 30 of the computer 26 for direct observation of flaws.

One key to white-noise induction is that different induction frequencies penetrate to different depths in a conductor. Thus the SQUIDs 32 response to certain frequency components contain some information about the depths that are being excited by the induction coil 40. The induction coils 40 produce a magnetic field at the work piece 18.

In one embodiment, the magnetic field is a plane wave. The equation for the plane wave (treated in one dimension for simplicity) in a conductor is

$$\frac{{\partial }^{2} ψ}{\partial {z}^{2}} - μσ \frac{\partial ψ}{\partial t} - μϵ \frac{{\partial }^{2} ψ}{\partial {t}^{2}} = 0. \qquad ( 1 )$$

Where μ is the magnetic permeability, ε is the electric permittivity, and σ is the conductivity. Starting with the solution being a plane wave where ω is the frequency,

ψ=ψ₀e^{i(kz-ax)} (2)

And plug (2) into (1) to find the dispersion relationship

k²=ω²με+iωμσ. (3)

“K” is of the form

k=α+iβ. (4)

Using (4) into (3) and separating the real and imaginary parts, yields

α²−β²=ω²με (5)

2αβ=ωμσ (6)

Combining (5) and (6) one can solve for α and β

$$\begin{matrix}α = ω {\sqrt{\frac{μϵ}{2}} [ \sqrt{1 + \frac{1}{{Q}^{2}}} + 1 ]}^{1 / 2} & ( 7 ) \\ β = ω {\sqrt{\frac{μϵ}{2}} [ \sqrt{1 + \frac{1}{{Q}^{2}}} - 1 ]}^{1 / 2} & ( 8 ) \\ where & \\ Q ≡ \frac{ωϵ}{σ} & ( 9 )\end{matrix}$$

Using (4) and (2) one can see that the form of the solution becomes

ψ=ψ₀e^{-βz}e^{i(az-ax)}

or what is known as a damped traveling wave. The amplitude is not constant but decreases with distance in the direction of propagation in the conductor. The loss of energy of the wave is due to resistive dissipation of energy into heat.

One can then consider at what depth, Δz or δ, the amplitude of the plane wave in the material has fallen to 1/e of its value at the surface.

$$δ = \frac{1}{β} \qquad ( 10 )$$

In the various cases considered, the materials are considered “good” conductors where the conductivity ranges from 5e⁷ (copper) to 1e⁵ (graphite). The frequency ranges from 0.1 Hz to 10 kHz. Thus the largest value of Q (using the permitivity of free space or ε=8.85e⁻¹² Cm⁻¹ V⁻¹) is on the order of e⁻¹² and we have the case where Q<<1.

When Q<<1 then we can keep only terms of order Q and 1/β reduces to

$$δ = \frac{1}{β} = \frac{1}{ω} \sqrt{\frac{2 Q}{μϵ} =} \sqrt{\frac{2}{ωμσ}} \qquad ( 11 )$$

This relationship tells us that the skin-depth, or the energy that the induction field penetrates into the work piece 18, is inversely related to the frequency of the induction signal. Or the higher the induction signal, the less deeply it will penetrate into the work piece 18.

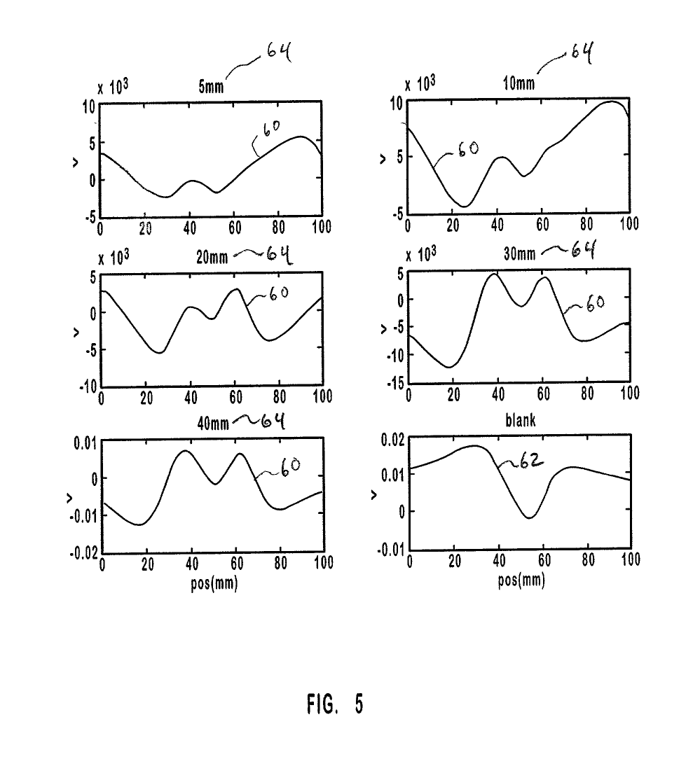

Referring now to FIG. 5, one embodiment of the magnetometer 10 of the present invention was tested. A 15 cm×20 cm rectangular induction coil 40 was placed as shown in FIG. 4. The induction coil 40 was designed to approximate the field seen from an infinitely long wire. The magnetic field from such a source falls off slowly as 1/r where r is the distance to the wire. In alternative embodiment, a circular induction coil 40 could be used where the fall off would have been as 1/r³. The configuration of this induction coil 40 maximizes the amount of power delivered to the deeper layers of the work piece 18 while also simplifying modeling efforts. The field from the vertical return leads cancels out.

In the test illustrated in FIG. 5, data are shown for a single frequency and a single SQUID. The phase and amplitude of each Squid's 32 response with respect to a single frequency reference signal was recorded at each point in the scan. This is done for clarity and because the feature of interest has no depth.

The spatial resolution of the instrument was tested using 150 mm×150 mm fiberglass plate coated with 100 μm of copper. Pairs of scratches, separated by various distances, were carved through the 100 μm copper layer. The scratches were each approximately 100 μm wide and 75 mm long. Spatial resolution in this example is defined as the ability to discern between a single scratch and two scratches. The results are show in FIG. 5, which plots the difference between the scratch pair data 60 and data 62 for a single scratch. Distances 64 between the scratch pairs are as labeled. It will be seen that in this test, significant deviations from the single scratch begin appearing around 20 mm.

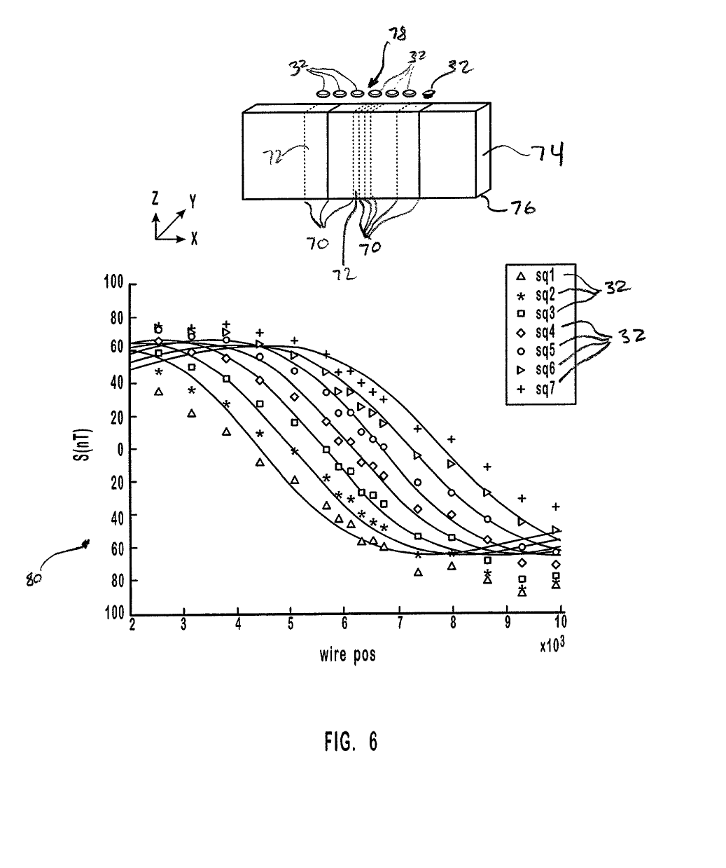

Referring now to FIG. 6, the spatial resolution was also tested for localized current sources with seven SQUIDs 32 on a single substrate. Wires 70 at varying separations 72 were wound on a 12 cm×15 cm×3.2 mm piece of plexiglass 74 placed on an edge 76 such that the 2.3 mm-long current elements were below the array 78 of SQUIDs 32 as shown in the upper drawing of FIG. 6.

The SQUID 32 array 78 was centered over the wire elements 70. The lift-off was z=4 mm. The wires 70 were activated individually at a single frequency and the magnetic field recorded by the seven SQUIDs 32. The data were fit to the analytic expression for a straight wire element of finite length

$${B}_{z} = \frac{{μ}_{0} Ix}{4 {πρ}^{2}} [ \frac{{L}_{2}}{\sqrt{{ρ}^{2} + {L}_{2}^{2}}} + \frac{{L}_{1}}{\sqrt{{ρ}^{2} + {L}_{1}^{2}}} ]$$

where L₁+L₂=3.2 mm, ρ=√(x²+z²), and y≈0 (L1≈L2). The current I was allowed to vary. Small corrections to x, z, L1 and L2 were also allowed to vary. The results of the fitting are shown in the graph 80 of FIG. 6. It will be appreciated by those of skill in the art that spatial resolution should be considered distinct from the ability to detect the presence of a feature. The present invention magnetometer 10 is sensitive to features that are much smaller in spatial extent.

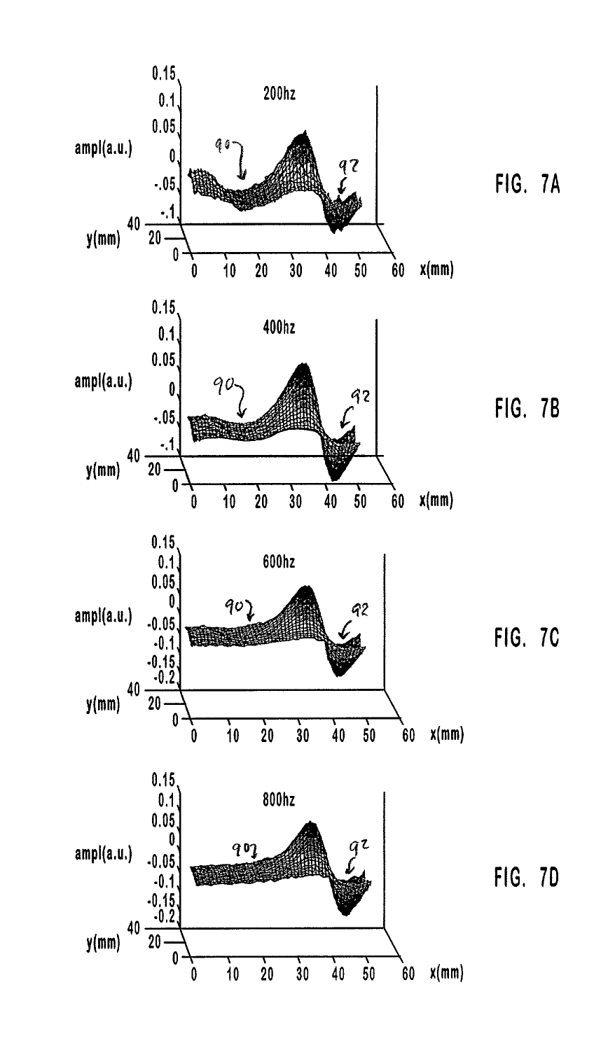

Referring now to FIGS. 7A through 7D, the ability of a white noise induction scheme to provide depth information was tested with plates of aluminum that were 15 cm×15 cm and 1.5 mm thick. The scheme utilized an induction signal generated by a white noise generator 42. The power spectrum is flat from direct current to 800 Hz before rolling off due to anti-aliasing filters. The random input and output sequences were processed by the computer 26 using in MATLAB software to determine their linear coherence and transfer function. Such analyses follow classical correlation and spectral analysis techniques.

The data were collected for one second at each step in the scan at 2 kHz sampling frequency. The data were processed and averaged in the frequency domain with approximately 1 Hz resolution. In this manner, each SQUID 32 response at multiple skin depths (frequencies) was simultaneously acquired and analyzed. The response at a specific skin depth for the material being examined was used to extract information about the feature depth.

The SQUIDs 32 response analyzed at frequencies from 200 Hz to 800 Hz for a stack of three plates. A bottom plate had a 5 mm diameter hole 90 located at x=10. A middle plate was blank. A top plate had a similar hole 92 located at x=40. The distance between the top plate and the Dewar bottom was approximately 2 mm. The holes 90, 92 appear as a two-lobed feature in the data. The bottom hole 90 (4.5 mm deep) is visible at frequencies less than 700 Hz where the skin-depth is greater than 3 mm. As the frequency increases, the skin depth decreases and the sensitivity to the buried feature also decreases. The hole 92 on the top becomes more visible as frequency is increased. The images in FIG. 6 were all acquired simultaneously during the data analysis.

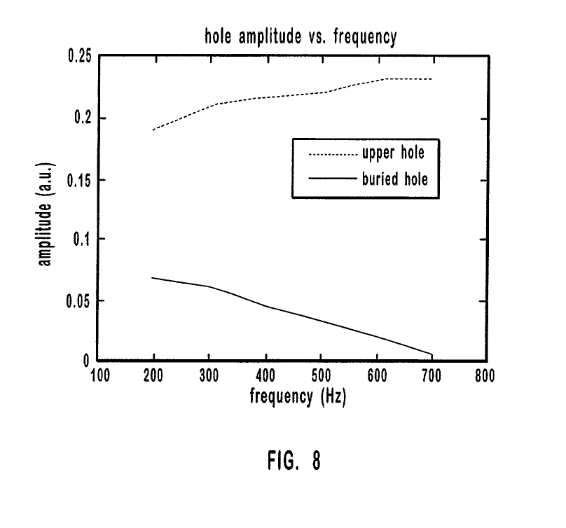

Referring now to FIG. 8, the amplitude of the two holes 90, 92, where amplitude is defined as the difference between the maximum and minimum amplitude of the lobes, is plotted as a function of frequency for the same data as shown in FIG. 7. As the frequency is increased, the amplitude of the hole on the surface continues to increase. The amplitude of the buried hole decreases as the frequency increases and the skin depth is reduced.

The magnetometer of the present invention is an improvement over existing non destructive evaluation systems. By using a linear array SQUIDs, all on the same substrate, and white noise induction techniques 42, a user can scan work piece at a large number of frequencies simultaneously. The depth that the induction field penetrates into the sample depends on the induction frequency.

The present invention may be embodied in other specific forms without departing from its structures, methods, or other essential characteristics as broadly described herein and claimed hereinafter. The described embodiments are to be considered in all respects only as illustrative, and not restrictive. The scope of the invention is, therefore, indicated by the appended claims, rather than by the foregoing description. All changes that come within the meaning and range of equivalency of the claims are to be embraced within their scope.

What is claimed and desired to be secured by United States Letters Patent is:

1. A magnetometer, comprising:
a magnetic field generator for inducing measurable magnetic fields in a work piece;
a plurality of super conducting quantum interference devices for measuring magnetic fields in work piece; and
a computer for interfacing with the magnetic field generator and the superconductivity quantum interferences devices to permit analysis of magnetic fields in the work piece.

2. The magnetometer of claim 1, wherein the magnetic field generator comprises an induction coil.

3. The magnetometer of claim 2, wherein the induction coil is driven by a white noise generator at multiple frequencies.

4. The magnetometer of claim 3, further comprising a frequency filter to facilitate the measurement of magnetic fields stimulated at predetermined frequencies.

5. The magnetometer of claim 1, wherein the magnetic field generator produces a substantially null field at the super conducting quantum interference devices.

6. The magnetometer of claim 1, wherein the plurality of super conducting quantum interference devices are linearly aligned.

7. The magnetometer of claim 1, wherein the super conducting quantum interference devices are formed on a single substrate.

8. The magnetometer of claim 7, wherein the spacing between each super conducting quantum interference device on the substrate is less than one millimeter.

9. The magnetometer of claim 7, wherein each super conducting quantum interference devices comprises a Josephson junction.

10. The magnetometer of claim 9, wherein the super conducting quantum interference devices are aligned at the Josephson junctions.

11. The magnetometer of claim 9, wherein the Josephson junction is a thirty degree bicrystal Josephson junction.

12. The magnetometer of claim 1, wherein each super conducting quantum interference device has a field sensitivity of between twenty nT/Φ₀ and one hundred and eighty nT/Φ₀.

13. The magnetometer of claim 1, wherein each super conducting quantum interference device has a field sensitivity of about one hundred nT/Φ₀.

14. The magnetometer of claim 1, further comprising and Dewar for housing the magnetic field generator.

15. The magnetometer of claim 14, wherein the Dewar has minimum thickness of less than about ten millimeters.

16. The magnetometer of claim 15, wherein the Dewar has a minimum thickness of about four millimeters.

17. The magnetometer of claim 14, wherein the Dewar contains liquid nitrogen.

18. The magnetometer of claim 17, wherein the magnetic field generator is substantially within the liquid nitrogen bath.

19. The magnetometer of claim 17, wherein the super conducting quantum interference devices are substantially within the liquid nitrogen bath.

20. The magnetometer of claim 1, further comprising a mover for moving the work piece adjacent the super conducting interference devices.

21. The magnetometer of claim 20, wherein the mover comprises a stepper motor.

22. The magnetometer of claim 20, wherein the mover comprises an x-y table.

23. The magnetometer of claim 1, wherein the magnetic field generator generates a pulse induction signal.

24. The magnetometer of claim 1, wherein the magnetic field generator generates a sine wave induction signal.

25. The magnetometer of claim 1, wherein the magnetic field generator generates a spike induction signal.

26. The magnetometer of claim 1, wherein the magnetic field generator comprises localized current.

27. A magnetometer, comprising:
a white noise generator for driving an induction coil to induce measurable currents in a work piece;
a magnetic field detector for measuring magnetic fields in a work piece; and
a computer for interfacing with the white noise generator and the magnetic field detector to permit analysis of magnetic fields in the work piece.

28. The magnetometer of claim 27, wherein the induction coil produces induction signals at multiple frequencies simultaneously.

29. The magnetometer of claim 27, further comprising a frequency filter to facilitate the measurement of magnetic fields stimulated at predetermined frequencies.

30. The magnetometer of claim 27, wherein the induction coil produces a substantially null field at the magnetic field detector.

31. The magnetometer of claim 27, wherein the magnetic field detector comprises a plurality of super conducting quantum interference devices.

32. The magnetometer of claim 31, wherein the plurality of super conducting quantum interference devices are linearly aligned.

33. The magnetometer of claim 31, wherein the super conducting quantum interference devices are formed on a single substrate.

34. The magnetometer of claim 33, wherein each super conducting quantum interference device comprises a Josephson junction.

35. The magnetometer of claim 34, wherein the super conducting quantum interference devices are aligned at the Josephson junction.

36. The magnetometer of claim 34, wherein the Josephson junction is a thirty degree bicrystal Josephson junction.

37. The magnetometer of claim 33, wherein the distance between each aligned super conducting quantum interference device is less than one millimeter.

38. The magnetometer of claim 27, wherein each super conducting quantum interference device has a field sensitivity of between twenty nT/Φ₀ and one hundred and eighty nT/Φ₀.

39. The magnetometer of claim 38, wherein each super conducting quantum interference device has a field sensitivity of about one hundred nT/Φ₀.

40. The magnetometer of claim 27, further comprising a Dewar for housing the magnetic field detector.

41. The magnetometer of claim 40, wherein the Dewar has a minimum thickness of less than about ten millimeters.

42. The magnetometer of claim 41, wherein the Dewar has a minimum thickness of about four millimeters.

43. The magnetometer of claim 27, wherein the Dewar contains liquid nitrogen.

44. The magnetometer of claim 43, wherein the induction coil is substantially within the liquid nitrogen bath.

45. The magnetometer of claim 43, wherein the magnetic field detector is substantially within the liquid nitrogen bath.

46. The magnetometer of claim 27, further comprising a mover for moving the work piece adjacent the super conducting interference devices.

47. The magnetometer of claim 46, wherein the mover is a stepper motor.

48. The magnetometer of claim 46, wherein the mover is an x-y table capable of moving the work piece in two directions.

49. A magnetometer, comprising:
a white noise generator for driving an induction coil to induce magnetic fields in a work piece at multiple frequencies;
a plurality of super conducting quantum interference devices for measuring magnetic fields in work piece;
a computer for interfacing with the white noise generator and the plurality of superconducting quantum interference devices to permit analysis of magnetic fields in the work piece;
a Dewar for housing the super conducting quantum interference devices; and
a mover for moving the work piece adjacent the super conducting quantum interference devices.

50. The magnetometer of claim 49, further comprising a frequency filter to facilitate the measurement of currents at predetermined frequencies.

51. The magnetometer of claim 49, wherein the induction coil produces a substantially null field at the super conducting quantum interference devices.

52. The magnetometer of claim 49, wherein the plurality of super conducting quantum interference devices are linearly aligned.

53. The magnetometer of claim 52, wherein the super conducting quantum interference devices are formed on a single substrate.

54. The magnetometer of claim 53, wherein the substrate of the super conducting quantum interference devices comprises a Josephson junction.

55. The magnetometer of claim 54, wherein the super conducting quantum interference devices are aligned at the Josephson junction.

56. The magnetometer of claim 49, wherein the Dewar has a minimum thickness of about four millimeters.

57. The magnetometer of claim 49, wherein the Dewar contains liquid nitrogen.

58. A method for testing a work piece with a magnetometer comprising a plurality of super conducting quantum interference devices, the method comprising:
driving a coil with a white noise generator to produce an induction signal for inducing eddy currents in the work piece;
measuring the magnetic fields produced by the eddy currents in the work piece with at least one super conducting interference device to create an output; and
analyzing the output to provide information relating to characteristics of the object.

59. The method of claim 58, wherein measuring is done by a plurality of super conducting interference devices in linear alignment.

60. The method of claim 59, wherein the super conducting quantum interference devices are formed on a single substrate.

61. The method of claim 59, wherein measuring comprises measuring the response of each super conducting quantum interference device to the induction signal.

62. The method of claim 61, wherein measuring comprises measuring the induction signal.

63. The method of claim 62, wherein analyzing comprises comparing each measured super conducting quantum interference device response to the measured induction signal.

64. The method of claim 58, wherein analyzing comprises determining a coherence of the output.

65. The method of claim 64, further comprising determining whether the coherence is acceptable.

66. The method of claim 58, wherein analyzing comprises determining a transfer function of the output.

67. The method of claim 58, wherein analyzing comprises factoring out errors due to undesired interference.
